(19) United States
(12) Patent Application Publication
(10) Pub. No.: US 2007/0229056 A1
(43) Pub. Date: Oct. 4, 2007

(54) Local oscillator diversity system for reducing spectrum analyzer synthesis spurs

(76) Inventor: Joseph M. Gorin, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/396,119

(22) Filed: Mar. 31, 2006

(51) Int. Cl. G01R 23/00; G01R 23/165

(52) U.S. Cl. 324/76.19; 324/76.29

(57) ABSTRACT

A local oscillator (LO) diversity system for a spectrum analyzer generates a first LO signal having a designated frequency and a first set of spurious signals, acquires a first record of an input signal applied to the spectrum analyzer with the first LO signal set to the designated frequency, generates a second LO signal having the designated frequency and a second set of spurious signals, wherein at least one spurious signal in the first set of spurious signals is at a frequency that is absent of a spurious signal in the second set of spurious signals. The LO diversity system acquires a second record of the input signal with the second LO signal set to the designated frequency, and then processes the first record and the second record to represent the frequency spectrum of the input signal.

### BACKGROUND OF THE INVENTION

Modern radio frequency (RF) spectrum analyzers have front-end frequency converters that frequency translate applied input signals into intermediate frequency (IF) signals that can be further processed by the RF spectrum analyzer. The front-end frequency converters typically include a mixer and a local oscillator that provide IF signals to an IF section within the RF spectrum analyzer. The frequency of the local oscillator is designated so that when a local oscillator signal provided by the local oscillator is mixed with signals that are applied to the RF spectrum analyzer, the resulting IF signal falls within the frequency range of the IF section. The IF section acquires records of samples of the IF signal and then applies signal processing to the records so that the frequency spectra of the input signals can be represented on a display of the RF spectrum analyzer.

The local oscillator signal provided to the mixer in the front-end frequency converter is typically synthesized using one or more phase locked loops. The phase locked loops cause the local oscillator signal to also have inherent spurious signals that result in synthesis spurs on the display along with the represented frequency spectrum of the input signal. When observing the frequency spectrum represented on the display of the spectrum analyzer, it is typically difficult to distinguish the synthesis spurs from the characteristics of the signals that are applied to the spectrum analyzer. Accordingly, it is advantageous to decrease the signal levels of the synthesis spurs attributable to the synthesis of the local oscillator signal in an RF spectrum analyzer.

### BRIEF DESCRIPTION OF THE DRAWINGS

FIG. 1 shows a simplified block diagram of a radio frequency (RF) spectrum analyzer suitable for implementing a local oscillator (LO) diversity system according to embodiments of the present invention.

FIG. 2 shows one example of a frequency spectrum represented on a display of the RF spectrum analyzer shown in FIG. 1.

FIG. 3 shows an example of the LO diversity system according to embodiments of the present invention.

FIGS. 4A-4E show examples of frequency spectra associated with the LO diversity system according to embodiments of the present invention.

### DETAILED DESCRIPTION

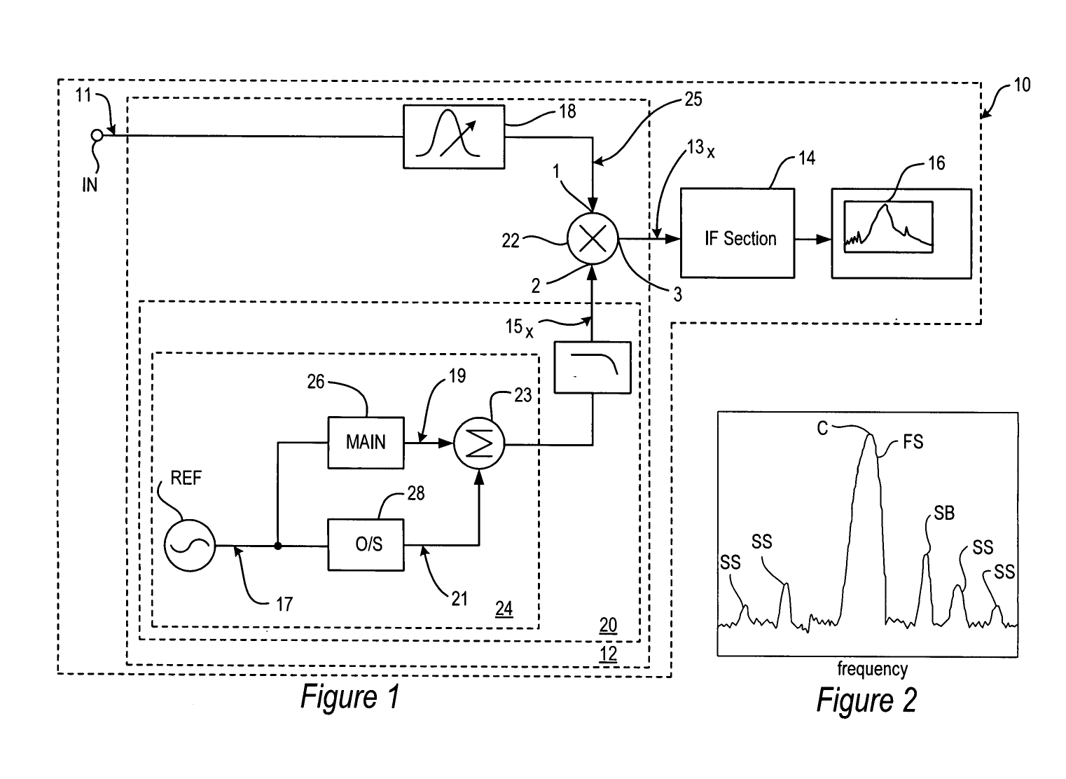

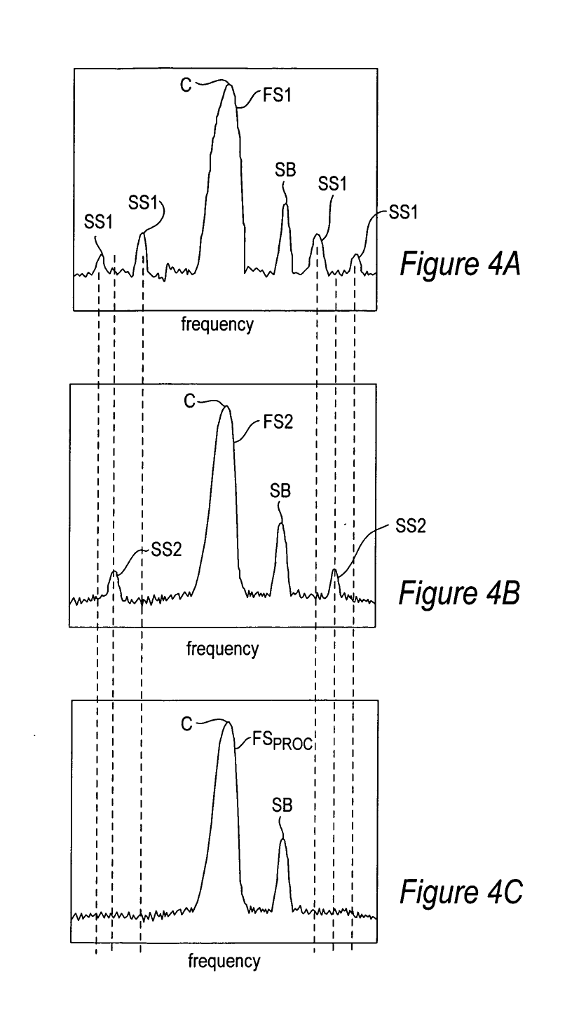

FIG. 1 shows a simplified block diagram of a conventional radio frequency (RF) spectrum analyzer, hereinafter RF spectrum analyzer 10, that receives input signals 11 at an input IN and provides representations of the frequency spectra of the input signals 11. The RF spectrum analyzer 10 is suitable for implementing a local oscillator (LO) diversity system 30 according to embodiments of the present invention (shown in FIG. 3). A description of the relevant operating features of the RF spectrum analyzer 10 is first provided for the purpose of illustrating the implementation of the LO diversity system 30 in the context of the RF spectrum analyzer 10.

The RF spectrum analyzer 10 includes a front-end frequency converter 12 that receives the input signals 11 that are applied to the RF spectrum analyzer 10. The front-end frequency converter 12 is coupled to an intermediate frequency (IF) section 14 that is coupled to a display 16 or other output device.

The front-end frequency converter 12 includes an input filter 18 and a local oscillator (LO) 20 that are coupled to a mixer 22. The input filter 18 typically includes a tuneable bandpass or lowpass filter that pre-selects the input signals 11 that are applied to the RF spectrum analyzer 10. Once the input signal 11 is filtered by the input filter 18, a resulting filtered signal 25 is applied to an input 1 of the mixer 22. An LO signal 15ₓ provided by the LO 20 is applied to an input 2 of the mixer 22. The mixer 22 has an output 3 that provides an IF signal 13ₓ to the IF section 14. The IF signal 13ₓ is a version of the input signal 11 that is translated in frequency by the LO signal 15ₓ, and influenced by the spurious signals and other spectral attributes of the LO signal 15ₓ.

In a typical RF spectrum analyzer 10, the LO signal 15ₓ is synthesized within the LO 20 with a dual phase locked loop (PLL) offset synthesizer 24 that includes a main frequency synthesis loop 26 and an offset frequency synthesis loop 28. The main frequency synthesis loop 26 and the offset frequency synthesis loop 28 are each frequency-referenced to a frequency standard REF that provides a reference signal 17 at a frequency f_{ref}. The main frequency synthesis loop 26 provides a signal 19 at a frequency f_{MAIN}=M*f_{ref}, whereas the offset frequency synthesis loop 28 provides a signal 21 at a frequency f_{O/S}=N.P*f_{ref}. Typically, M and N are integers and P is a fraction of finite resolution, such that 0≦P<1. The term N.P in the frequency f_{O/S}=N.P*f_{ref} represents integer and fractional portions of a number that is equal to the sum N+P. The dual PLL offset synthesizer 24 includes a signal summer 23 that sums the signal 19 from the main frequency synthesis loop 26 and the signal 21 from the offset frequency synthesis loop 28 to provide an LO signal 15ₓ at a frequency f_{LO}=(M+N.P)*f_{ref}.

In addition to providing the LO signal 15ₓ at the frequency f_{LO}, the dual PLL offset synthesizer 24 also introduces a set of unwanted spurious signals on the LO signal 15ₓ. These spurious signals typically occur at frequencies established by the values of M, N and P that are designated in the synthesis of the LO signal 15ₓ by the main frequency synthesis loop 26 and the offset frequency synthesis loop 28 of the dual PLL offset synthesizer 24.

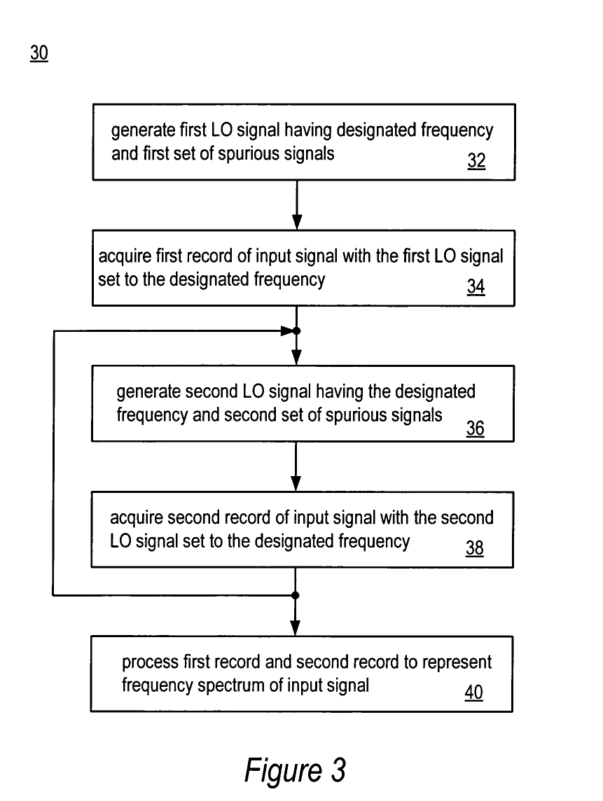

The LO signal 15ₓ provided by the dual PLL offset synthesizer 24 is mixed with the input signal 11 to provide the IF signal 13ₓ to the IF section 14. The IF section 14 filters the IF signal 13ₓ and acquires one or more records of samples of the input signal 11, where the input signal 11 is represented by the frequency-translated version of the input signal 11 that is provided by the IF signal 13ₓ. The IF section 14 transforms the one or more records of samples to provide a representation of the frequency spectrum of the input signal 11 on the display 16 of the RF spectrum analyzer 10, typically by performing a Fast Fourier Transform (FFT) and other signal processing on the one or more records. When the one or more records of the input signal 11 are acquired with the signals 19, 21 having a single combination of frequencies f_{MAIN}, f_{O/S}, the represented frequency spectrum FS of the input signal 11 on the display 16 includes the spectral attributes of the input signal 11, such as a carrier C and a sideband SB, and synthesis spurs SS that are attributable to the set of unwanted spurious signals present on the LO signal 15ₓ, as shown in the example frequency spectrum FS of FIG. 2. When observing the represented frequency spectrum FS on the display 16, it can be difficult to distinguish the synthesis spurs SS from the attributes of the input signals 11 that are applied to the RF spectrum analyzer 10. The vertical axis of the display 16 of the RF spectrum analyzer 10 typically represents the signal level of the frequency spectrum versus frequency, which is typically represented on the horizontal axis of the display 16.

FIG. 3 shows an example of the local oscillator (LO) diversity system 30 according to embodiments of the present invention, implemented in the context of the RF spectrum analyzer 10 shown in FIG. 1. A step 32 of the LO diversity system 30 includes generating a first LO signal 15₁ at a designated frequency f_{LO}. In the context of the RF spectrum analyzer 10, step 32 includes synthesizing the first LO signal 15₁ with the signals 19, 21 having a first combination of frequencies f_{MAIN1}, f_{O/S1}, provided by the main frequency synthesis loop 26 and the offset frequency synthesis loop 28, respectively, of the dual PLL offset synthesizer 24.

One example of the synthesizing the first LO signal 15₁, provided for the purpose of illustration, includes setting the frequency of the signal 19 to a frequency f_{MAIN1}=(M₀+k)*f_{ref} and setting the frequency of the signal 21 to a frequency f_{O/S1}=((N₀-k).P)*f_{ref}. In this example, M₀, N₀, k are integers and P₀ is a fraction of finite resolution, such that 0≦P0<1. The term N₀.P₀ in the frequency f_{O/S1}=N₀.P₀*fref represents integer and fractional portions of a number equal to the sum N₀+P₀. The signals 19, 21 at the combination of frequencies f_{MAIN1}, f_{O/S1} result in the first LO signal 15₁ having the frequency f_{LO}=((M₀+k+(N₀−k).P₀)f_{ref}=(M₀+N₀.P₀)f_{ref}. However, in addition to the signal at the designated frequency f_{LO}, the first LO signal 15₁ also includes a first set of spurious signals at frequencies determined by the values of M₀+k, and (N₀−k).P₀ associated with the synthesis of the first LO signal 15₁ by the dual PLL offset synthesizer 24.

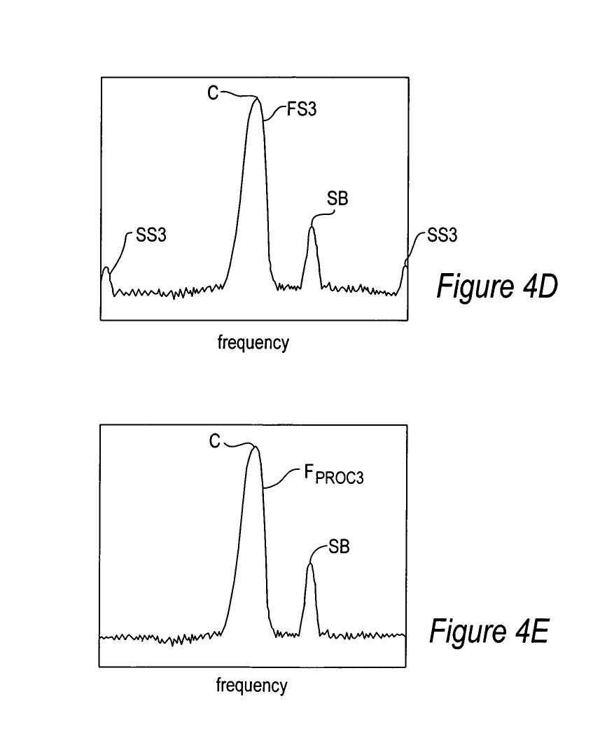

A step 34 of the LO diversity system 30 includes acquiring a first record of the input signal 11 that is applied to the RF spectrum analyzer 10. In the context of the RF spectrum analyzer 10, the first record is acquired with the LO section 20 providing the first LO signal 15₁ at the frequency f_{LO} designated in step 32, provided by the signals 19, 21 having the first combination of frequencies f_{MAIN1}, f_{O/S1}. The first record of the input signal 11 is acquired by mixing the input signal 11 applied to the front-end frequency converter 12 with the first LO signal 15₁ to provide an IF signal 13, to the IF section 14, acquiring one or more records of samples of the IF signal 13₁, and then transforming the one or more records of samples to provide a representation the frequency spectrum FS1 (shown in FIG. 4A) of the input signal 11. Transforming the one or more records typically includes performing an FFT and other signal processing on the records sufficient to provide the representation of the frequency spectrum FS1 of the input signal 11 on the display 16. The IF signal 13₁ is a version of the input signal 11 that is translated in frequency by the LO signal 15₁, and is influenced by the first set of spurious signals present in the LO signal 15₁. Accordingly, the frequency spectrum FS1 also includes synthesis spurs SS1 at a first set of frequencies that correspond to the first set of spurious signals that are associated with synthesizing the first LO signal 15₁. FIG. 4A shows one example of the representation of the frequency spectrum FS1 on the display 16 of the RF spectrum analyzer 10, established based on the first record acquired in step 34.

A step 36 of the LO diversity system 30 includes generating a second LO signal 152 at the same frequency f_{LO} designated in step 32. In the context of the RF spectrum analyzer 10, the step 36 includes synthesizing the second LO signal 152 with the signals 19, 21 having a second combination of frequencies f_{MAIN2}, f_{O/S2}, that are provided by the main frequency synthesis loop 26 and the offset frequency synthesis loop 28 of the dual PLL offset synthesizer 24.

One example of the synthesizing the second LO signal 15₂, provided for the purpose of illustration, includes setting the frequency of the signal 19 to a frequency f_{MAIN2}=(M₀+2k)*f_{ref} and setting the frequency of the signal 21 to a frequency f_{O/S2}=(N₀−2k).P)*f_{ref}. The signals 19, 21 at the combination of frequencies f_{MAIN2}, f_{O/S2} in the second LO signal 15₂ results in the second LO signal 15₂ having the frequency f_{LO}=((M₀+2k+(N₀−2k).P₀)f_{ref}=(M₀+N₀.P₀)f_{ref}. In addition to the signal at the designated frequency f_{LO}, the second LO signal 15₂ also includes a second set of spurious signals at frequencies determined by the values of M₀+2k, and (N₀−2k).P₀ associated with the synthesis of the signals 19, 21 by the dual PLL offset synthesizer 24. The frequencies f_{MAIN1}, f_{O/S1} and f_{MAIN2}, f_{O/S2} of the signals 19, 21 that are each combined to synthesize the LO signals 15₁, 15₂, respectively, result in at least one spurious signal in the first set of spurious signals being at a frequency, that in the second set of spurious signals is absent of a spurious signal.

A step 38 of the LO diversity system 30 includes acquiring a second record of the input signal 11 that is applied to the RF spectrum analyzer 10. In the context of the RF spectrum analyzer 10, the second record is acquired with the LO 20 providing the second LO signal 15₂ at the frequency f_{LO}=(M₀+N₀.P₀)f_{ref} designated in step 32, provided by the signals 19, 21 having the second combination of frequencies f_{MAIN2}, f_{O/S2}. The second record of the input signal 11 is acquired by mixing the input signal 11 applied to the front-end frequency converter 12 with the second LO signal 15₂, to provide an IF signal 13₂ to the IF section 14, acquiring one or more records of samples of the IF signal 13₂, and then transforming the one or more records of samples to provide a representation of the frequency spectrum FS2 (shown in FIG. 4B) of the input signal 11. Transforming the one or more records of samples typically includes performing an FFT and other signal processing on the acquired records sufficient to provide the representation of the frequency spectrum FS2 of the input signal 11 on the display 16. FIG. 4B shows one example representation of the frequency spectrum FS2 on the display 16 of the RF spectrum analyzer 10, resulting from the second record acquired in step 38. The IF signal 13₂ is a frequency translated version of the input signal 11 that is translated in frequency by the LO signal 15₂, and is influenced by the second set of spurious signals present in the second LO signal 15₂. Accordingly, the frequency spectrum FS2 includes synthesis spurs SS2 at a second set of frequencies that correspond to the second set of spurious signals that are associated with synthesizing the second LO signal 15₂. At least one of the frequencies in the first set of frequencies is absent from the second set of frequencies. For example, the frequency spectrum FS1 (shown in FIG. 4A) has synthesis spurs SS1 at frequencies where the synthesis spurs SS2 in the frequency spectrum FS2 (shown in FIG. 4B) are absent. In this example, there are also synthesis spurs SS2 in the frequency spectrum FS2 at frequencies where the synthesis spurs SS1 in the frequency spectrum FS1 are absent.

A step 40 of the LO diversity system 30 includes processing the represented frequency spectra FS1, FS2 that are associated with the records of the input signal 11 acquired in steps 34, 38. The processing typically reduces the signal level of the synthesis spurs SS1, SS2 that correspond to the sets of spurious signals associated with synthesizing the LO signals 15₁, 15₂, to provide a resulting frequency spectrum FS_{PROC} of the input signal 11 on the display 16. FIG. 4C shows one example of the resulting frequency spectrum FS_{PROC} of the input signal 11 that results from processing the two records of the input signal 11 acquired in steps 34, 38 and shown in FIGS. 4A and 4B, respectively. In this example, the processing of the acquired records includes selecting, at each frequency in the represented frequency spectra FS1, FS2 of the input signal 11, the signal level that is equal to that of the one of the frequency spectrum FS1 and the frequency spectrum FS2 with the lower signal level to provide the resulting frequency spectrum FS_{PROC} of the input signal 11. Accordingly, in the frequency spectrum F_{PROC}, attributes of the input signal 11, such as a carrier C and a sideband SB, are distinguished from the synthesis spurs SS1, SS2 present in each of the frequency spectra FS1, FS2, due to diversity of the spurious signals associated with the synthesis of the LO signals 15₁, 15₂ by the LO 20.

According to alternative embodiments of the LO diversity system 30, step 36 and step 38 are both repeated one or more times, wherein step 38 is repeated with each repetition of step 36. Each repetition of step 36 includes generating another LO signal 15ₓ at the frequency f_{LO} designated in step 32. In the context of the RF spectrum analyzer 10, each generated LO signal 15ₓ is synthesized with signals 19, 21 that have a different combination of frequencies f_{MAINX}, f_{O/SX}, provided by the main frequency synthesis loop 26 and the offset frequency synthesis loop 28, respectively, of the dual PLL offset synthesizer 24. Each combination of frequencies f_{MAINX}, f_{O/SX} results in each of the generated LO signals 15ₓ, having a corresponding set of spurious signals. At least one spurious signal in the first set of spurious signals occurs at a frequency at which a spurious signal is absent in at least one of the other sets of spurious signals associated with synthesizing the multiple LO signals 15ₓ in the repetitions of step 36.

Each repetition of step 38 includes acquiring another record of the input signal 11. Each record is acquired with the LO 20 providing a corresponding one of the LO signals 15ₓ, that is generated in each corresponding repetition of step 36. Each record acquired in each repetition of step 38 includes synthesis spurs SSx at a corresponding set of frequencies.

An example is provided wherein steps 36 and 38 are repeated a total of two times, for the purpose of illustrating alternative embodiments of the LO diversity system 30. In this example, the first repetition of steps 36, 38 provides the frequency spectrum FS2 shown in FIG. 4B. In the second repetition of step 36, an LO signal 153 is synthesized with the signals 19, 21 having a third combination of frequencies f_{MAIN3}, f_{O/S3} provided by the main frequency synthesis loop 26 and the offset frequency synthesis loop 28, respectively, of the dual PLL offset synthesizer 24. This third combination of frequencies f_{MAIN3}, f_{O/S3} results in the LO signal 153 having an associated third set of spurious signals. At least one spurious signal in the first set of spurious signals occurs at a frequency at which spurious signals are absent in at least one of the second and third sets of spurious signals associated with synthesizing the LO signals 152, 153.

The second repetition of step 38 includes acquiring a third record of the input signal 11 with the LO 20 providing the LO signal 153. The third record is acquired by mixing the input signal 11 applied to the front-end frequency converter 12 with the LO signal 153 to provide an IF signal 133 to the IF section 14, acquiring one or more records of samples of the IF signal 133, and then transforming the one or more records to provide a representation of the frequency spectrum FS3 (shown in FIG. 4D) of the input signal 11. Transforming the one or more records typically includes performing an FFT and other signal processing on the acquired one or more records sufficient to provide the representation of the frequency spectrum FS3 of the input signal 11 on the display 16. FIG. 4D shows one example representation of the frequency spectrum FS3 on the display 16 of the RF spectrum analyzer 10, established based on the third record acquired in the second repetition of step 38. The IF signal 133 is a version of the input signal 11 that is translated in frequency by the LO signal 153, and is influenced by the third set of spurious signals associated with synthesizing the third LO signal 153. Accordingly, the third set of spurious signals causes synthesis spurs SS3 in the frequency spectrum FS3 at a third set of frequencies that correspond to the third set of spurious signals associated with synthesizing the LO signal 153. At least one of the frequencies in the first set of frequencies is absent in at least one of the second set of frequencies and the third set of frequencies.

According to the alternative embodiments, the step 40 of the LO diversity system 30 includes processing the represented frequency spectra FS1, FS2, FS3 that are established based on the records of the input signal 11 acquired in step 34, and the two repetitions of step 38. The processing typically reduces the signal level of the synthesis spurs SS1, SS2, SS3 that correspond to the sets of spurious signals associated with synthesizing the LO signals 151, 152, 153 in a resulting frequency spectrum FS_{PROC3} of the input signal 11 on the display 16. FIG. 4E shows one example of the resulting frequency spectrum FS_{PROC3} of the input signal 11 that results from processing the three records of the input signal 11 shown in FIGS. 4A, 4B, 4D, respectively. In the example frequency spectra FS1, FS2, FS3, shown in FIGS. 4A, 4B, 4D, respectively, the frequency spectrum FS1 (shown in FIG. 4A) has synthesis spurs SS1 at frequencies where the synthesis spurs SS2 in the frequency spectrum FS2 (shown in FIG. 4B) are absent, and where the synthesis spurs SS3 in the frequency spectrum FS3 (shown in FIG. 4D) are absent. The frequency spectrum FS2 (shown in FIG. 4B) has synthesis spurs SS2 at frequencies where the synthesis spurs SS1 in the frequency spectrum FS1 (shown in FIG. 4A) are absent, and where the synthesis spurs SS3 in the frequency spectrum FS3 (shown in FIG. 4D) are absent. The frequency spectrum FS3 (shown in FIG. 4D) has synthesis spurs SS3 at frequencies where the synthesis spurs SS1 in the frequency spectrum FS1 (shown in FIG. 4A) are absent, and where the synthesis spurs SS2 in the frequency spectrum FS2 (shown in FIG. 4B) are absent.

According to these alternative embodiments of the LO diversity system 30, the step 40 includes determining the median signal level of the frequency spectra FS1, FS2, FS3, at each frequency in the represented frequency spectra FS1, FS2, FS3 of the input signal 11. The resulting frequency spectrum FS_{PROC3} of the input signal 11 has the median signal level of the frequency spectra FS1, FS2, FS3. The median signal level is typically determined by applying a median filter to the frequency spectra, or by a computation performed by a processor (not shown) included in the RF spectrum analyzer 10.

In the frequency spectrum F_{PROC3}, attributes of the input signal 11, such as the carrier C and the sideband SB, are distinguished from the synthesis spurs SS1, SS2, SS3 present in each of the frequency spectra FS1, FS2, FS3, due to diversity of the spurious signals associated with the synthesis of the LO signals 151, 152, 153 by the LO 20.

In alternative embodiments of the LO diversity system 30, wherein the steps 36 and 38 are repeated multiple times to acquire a greater number of records and represented frequency spectra of the input signal 11, the step 40 includes determining, at each frequency in multiple represented frequency spectra of the input signal 11, the median signal level of the multiple frequency spectra, the minimum signal level of the multiple frequency spectra, or any other suitable processing of the frequency spectra to provide a resulting frequency spectrum of the input signal wherein synthesis spurs in the frequency spectra are reduced.

In the embodiments wherein the LO diversity system 30 is implemented in the context of the RF spectrum analyzer 10, shown in FIG. 1, the frequencies of the signals 19, 21, respectively, are set by the processor internal to the RF spectrum analyzer 10 and coupled to the LO 20. The processor typically also controls the acquisitions of records of samples of the IF signals 13ₓ in the IF section 14, the transforming of the records to provide the representations of the frequency spectra of the input signal 11, and the processing of the acquired records in step 40 to provide a resulting frequency spectrum of the input signal 11 having synthesis spurs with reduced signal levels. According to alternative embodiments, the LO diversity system 30 is implemented under the control of a computer or other type of processor that is external to the RF spectrum analyzer 10. In these embodiments the LO diversity system 30 includes a computer readable medium with instructions to implement the steps 32-40 of the LO diversity system 30.

For the purpose of illustrating embodiments of the LO diversity system 30, the LO diversity system 30 is shown implemented in the context of the RF spectrum analyzer 30 that includes an LO 20 with a dual PLL offset synthesizer 24. A typical example of this type of RF spectrum analyzer 10, with capabilities that are suitable for implementing the LO diversity system 30, is an AGILENT TECHNOLOGIES, INC. PSA series spectrum analyzer model E4440A. However, the LO diversity system 30 is alternatively implemented using any other type of spectrum analyzer, receiver, instrument, or system that has capability to generate an LO signal at a designated frequency in two or more alternative or diverse ways, wherein each of the diverse ways generating the LO signal 15ₓ provides a corresponding set of spurious signals. The sets of spurious signals typically result in synthesis spurs at corresponding sets of frequencies, wherein frequencies in each set are misaligned with frequencies in the other sets of frequencies, as shown for example in FIGS. 4A, 4B, 4D.

While the embodiments of the present invention have been illustrated in detail, it should be apparent that modifications and adaptations to these embodiments may occur to one skilled in the art without departing from the scope of the present invention as set forth in the following claims.

1. A local oscillator (LO) diversity system for a spectrum analyzer, comprising:
(a) generating a first LO signal having a designated frequency and a first set of spurious signals;
(b) acquiring a first record of an input signal applied to the spectrum analyzer with the first LO signal set to the designated frequency;
(c) generating a second LO signal having the designated frequency and a second set of spurious signals, wherein at least one spurious signal in the first set of spurious signals is at a frequency that is absent of a spurious signal in the second set of spurious signals;
(d) acquiring a second record of the input signal with the second LO signal set to the designated frequency; and
(e) processing the first record acquired in (b) and the second record acquired in (d) to represent the frequency spectrum of the input signal on a display of the spectrum analyzer.

2. The system of claim 1 wherein the first record includes synthesis spurs at a first set of frequencies and the second record includes synthesis spurs at a second set of frequencies, wherein at least one of the frequencies in the first set of frequencies is absent in the second set of frequencies.

3. The system of claim 1 wherein generating the first LO signal having the designated frequency includes summing a first signal and a second signal that are synthesized with a first combination of frequencies, and generating the second LO signal having the designated frequency includes summing a third signal and a fourth signal that are synthesized with a second combination of frequencies.

4. The system of claim 3 wherein the first signal and the third signal are synthesized with a main frequency synthesis loop of a dual phase locked loop (PLL) offset synthesizer, and wherein the second signal and the fourth signal are synthesized with an offset frequency synthesis loop of the dual phase locked loop (PLL) offset synthesizer.

5. The system of claim 1 wherein (b) includes mixing the input signal with the first LO signal to provide a first IF signal, acquiring one or more records of samples of the first IF signal, and transforming the one or more records of samples to provide a first frequency spectrum, and wherein (d) includes mixing the input signal with the second LO signal to provide a second IF signal, acquiring one or more records of samples of the second IF signal, and transforming the one or more records of samples to provide a second frequency spectrum.

6. The system of claim 5 wherein, at each frequency within the frequency spectrum of the input signal represented in (e), the frequency spectrum of the input signal represented in (e) has a signal level that is set equal to the signal level of the one of the first frequency spectrum and the second frequency spectrum that has the lower signal level.

7. A local oscillator (LO) diversity system, comprising:
(a) generating a first LO signal having a designated frequency and a first set of spurious signals;
(b) acquiring a first record of an input signal applied to a spectrum analyzer with the first LO signal set to the designated frequency;
(c) generating one or more second LO signals each having the designated frequency, each of the one or more second LO signals having a corresponding set of spurious signals, wherein at least one spurious signal in the first set of spurious signals occurs at at least one frequency at which a spurious signal is absent in at least one of the one or more sets of spurious signals that correspond to the one or more second LO signals;
(d) acquiring one or more second records of the input signal with each of the one or more second records each acquired with a corresponding one of the one or more second LO signals set to the designated frequency; and
(e) processing the first record acquired in (b) and the one or more second records acquired in (d) to represent the frequency spectrum of the input signal on a display of the spectrum analyzer.

8. The system of claim 7 wherein the first record includes synthesis spurs at a first set of frequencies and the one or more second records include synthesis spurs at corresponding one or more second sets of frequencies, wherein at least one of the frequencies in the first set of frequencies is absent in at least one of the one or more second sets of frequencies.

9. The system of claim 7 wherein the one or more acquired second records includes at least two second records, and wherein (e) includes at each frequency, taking the median of a first spectrum established from the first acquired record and at least two second frequency spectra established from the at least two second records to provide the frequency spectrum of the input signal represented in (e).

10. The system of claim 7 wherein generating the first LO signal having the designated frequency includes summing a first signal and a second signal that are synthesized with a first combination of frequencies, and generating the one or more second LO signals at the designated frequency includes summing one or more third signals and corresponding one or more fourth signals that are synthesized with corresponding one or more second combinations of frequencies.

11. The system of claim 10 wherein the first signal and the one or more third signals are synthesized with a main frequency synthesis loop of a dual phase locked loop (PLL) offset synthesizer, and wherein the second signal and the one or more fourth signals are synthesized with an offset frequency synthesis loop of the dual phase locked loop (PLL) offset synthesizer.

12. The system of claim 7 wherein (b) includes mixing the input signal with the first LO signal to provide a first IF signal, acquiring at least one record of samples of the first IF signal, and transforming the at least one record of samples to provide a first frequency spectrum, and wherein (d) includes mixing the input signal with the one or more second LO signals to provide one or more second IF signals, acquiring at least one record of samples of each of the one or more second IF signals, and transforming the at least one record of samples of each of the one or more second IF signals to provide a corresponding one or more second frequency spectra.

13. The system of claim 12 the one or more acquired second records includes at least two second records, and wherein (e) includes at each frequency, taking the median of a first spectrum established from the first acquired record and at least two second frequency spectra established from the at least two second records to provide the frequency spectrum of the input signal represented in (e).

14. A local oscillator (LO) diversity system for a spectrum analyzer, comprising:
(a) generating a first LO signal with a local oscillator of the spectrum analyzer, the first LO signal having a designated frequency and a first set of spurious signals;
(b) acquiring a first record of an input signal applied to the spectrum analyzer within an intermediate frequency (IF) section of the spectrum analyzer, wherein the first LO signal set to the designated frequency;
(c) generating one or more second LO signals with the local oscillator, each of the one or more second LO signals having the designated frequency, and each of the one or more second LO signals having a corresponding set of spurious signals, at least one spurious signal in the first set of spurious signals occurring at at least one frequency at which a spurious signal is absent in at least one of the one or more sets of spurious signals that correspond to the one or more second LO signals;
(d) acquiring one or more second records of the input signal within the IF section, wherein each of the one or more second records is acquired with a corresponding one of the one or more second LO signals set to the designated frequency; and
(e) processing the first record acquired in (b) and the one or more second records acquired in (d) to represent the frequency spectrum of the input signal on a display of the spectrum analyzer.

15. The system of claim 14 wherein the first record includes synthesis spurs at a first set of frequencies and the one or more second records of the input signal include synthesis spurs at corresponding one or more second sets of frequencies, wherein at least one of the frequencies in the first set of frequencies is absent in at least one of the one or more second sets of frequencies.

16. The system of claim 14 wherein the one or more acquired second records includes at least two second records, and wherein (e) includes at each frequency, taking the median of a first spectrum established from the first acquired record and at least two second frequency spectra established from the at least two second records to provide the frequency spectrum of the input signal represented in (e).

17. The system of claim 14 wherein generating the first LO signal having the designated frequency includes summing a first signal and a second signal that are synthesized with a first combination of frequencies, and generating the one or more second LO signals at the designated frequency includes summing one or more third signals and corresponding one or more fourth signals that are synthesized with corresponding one or more second combinations of frequencies.

18. The system of claim 17 wherein the first signal and the one or more third signals are synthesized with a main frequency synthesis loop of a dual phase locked loop (PLL) offset synthesizer within the local oscillator, and wherein the second signal and the one or more fourth signals are synthesized with an offset frequency synthesis loop of the dual phase locked loop (PLL) offset synthesizer.

19. The system of claim 14 wherein (b) includes mixing the input signal with the first LO signal with a mixer to provide a first IF signal, acquiring at least one record of samples of the first IF signal, and transforming the at least one record of samples to provide a first frequency spectrum, and wherein (d) includes mixing the input signal with the one or more second LO signals with the mixer to provide one or more second IF signals, acquiring at least one record of samples of each of the one or more second IF signals, and transforming the at least one record of samples of each of the one or more second IF signals to provide a corresponding one or more second frequency spectra.

20. The system of claim 19 wherein the one or more acquired second records includes at least two second records, and wherein (e) includes at each frequency, taking the median of a first spectrum established from the first acquired record and at least two second frequency spectra established from the at least two second records to provide the frequency spectrum of the input signal represented in (e).
